(19) United States
(12) Patent Application Publication
(10) Pub. No.: US 2009/0273971 A1
(43) Pub. Date: Nov. 5, 2009

(54) CONTINUOUSLY DRIVING NON-VOLATILE MEMORY ELEMENT

(75) Inventor: CORNELIUS PETRUS ELISABETH SCHEPENS, Jr Beuningen (NL)

Correspondence Address: PATTERSON & SHERIDAN, L.L.P., 3040 POST OAK BOULEVARD, SUITE 1500, HOUSTON, TX, 77056, US

(73) Assignee: CAVENDISH KINETICS INC., San Jose, CA (US)

(21) Appl. No.: 12/433,589

(22) Filed: Apr. 30, 2009

Related U.S. Application Data
(60) Provisional application No. 61/126,073, filed on Apr. 30, 2008.

(51) Int. Cl. G11C 11/50; G11C 7/10; G11C 7/00

(52) U.S. Cl. 365/166; 365/189.05; 365/189.12

(57) ABSTRACT

Embodiments discussed herein generally relate to utilizing non-volatile memory elements to continuously drive other circuitry. There are many advantages to utilizing non-volatile memory to continuously drive other circuitry. For example, back end of the line (BEOL) compatible process may be used to fabricate the non-volatile memory elements that does not affect any front end of the line (FEOL) devices. This allows for an earlier integration of non-volatile technology into the latest state-of-the-art semiconductor process nodes. This is specifically important for FPGA and CPLDs, which make use of the latest process nodes.

### CROSS-REFERENCE TO RELATED APPLICATIONS

This application claims benefit of U.S. Provisional Patent Application Ser. No. 61/126,073 (1912.038597), filed Apr. 30, 2008, which is herein incorporated by reference.

### BACKGROUND OF THE INVENTION

1. Field of the Invention

Embodiments disclosed herein generally relate to non-volatile registers, based on MEMS switches, whether they are arranged as a single register, a row of registers, a row of shift registers or an array of latches fed by registers or shift registers. The non-volatile memory elements may continuously drive another piece of circuitry.

2. Description of the Related Art

There are many analog and mixed-signal chips (“AMS” chips), which utilize some form of fine-tuning to achieve a proper functioning of the device within its specifications. This fine-tuning is either done once or only a few times and the information needs to be stored. As this information usually needs to be kept when the power is switched off, it requires non-volatile memory elements to store the information. The transistor(s), which is(are) used as a switch in a network (resistive, capacitive, inductive or any combination) to provide the right fine-tuned value, needs to be driven continuously.

The above analog mixed signal application is only one example, where typically only 1 to 1000 memory elements are required on such AMS chip. A field programmable gate array (FPGA) or complex programmable logic device (CPLD) is a digital device which uses thousands to millions of memory elements continuously driving other digital circuits. These FPGAs or CPLDs are large digital chips, which tend to be made in the latest or smallest available technology node in order to provide the largest amount of programmable elements to create large logic circuits at low cost, low power and high speed. As non-volatile memory technology is usually not available in these latest technology nodes, SRAMS and shift registers are used to store this information, which is read in during the power-up sequence from an external non-volatile memory. This approach requires a large amount of board space, might be more costly and adds a security risk as it will be easier to counterfeit the user-programmed circuitry.

Therefore, there is a need in the art for non-volatile memory elements to continuously drive other circuitry.

### SUMMARY OF THE INVENTION

It is possible to create a non-volatile memory element with an output continuously driving other circuits. The difference between the MEMS-based switch memory element and other non-volatile memory elements rely on the fact that the MEMS-based switch off-state is an infinite resistance, disregarding any small leakage effects, which will be less than the leakage of a CMOS transistor in the same process. This allows building circuitry, which doesn't require any special conditioning during power-up, as a combination of two switches can be used connected between the two power rails, where one switch is off and the other switch is on, always blocking any DC current.

When any of the other non-volatile technologies are used to create a continuously driving memory element, a (analog) detection circuit is used to determine the difference between a ‘0’ and a ‘1’ (e.g., to determine the difference between a low and a high resistance) or a continuous current is used to provide the digital value. A combination of two MEMS-switches will provide a direct ‘digital signal’ without drawing any DC current. For example, a floating gate transistor may be used in a latch circuit without any need for DC current. In such a situation, the leakage may be twice as much for the cantilever concept.

In one embodiment, a shift register chain is disclosed. The shift register chain includes a flip flop and one or more NOR gates coupled to the flip flop. The shift register chain also may include a first non-volatile memory element coupled to the one or more NOR gates and comprising a first pull-off electrode. The first non-volatile memory element may include a first contact electrode, a first pull-in electrode disposed adjacent the first contact electrode, and a first bi-stable cantilever electrode movable between an open position and a closed position. The shift register chain may also include a second non-volatile memory element coupled to the one or more NOR gates. The second non-volatile memory element may include a second pull-off electrode, a second contact electrode, a second pull-in electrode disposed adjacent the second contact electrode, and a second bi-stable cantilever electrode movable between an open position and a closed position. The shift register chain may also optionally include an inverter coupled to both the first contact electrode and the second contact electrode to allow for a higher drive current.

In another embodiment, a shift register chain is disclosed. The shift register chain includes a plurality of flip flops, each flip flop having a first NOR gate and a second NOR gate coupled thereto. The shift register chain also includes a first non-volatile memory element coupled to the first NOR gate. The first non-volatile memory element includes a first pull-off electrode, a first contact electrode, a first pull-in electrode disposed adjacent the first contact electrode, and a first bi-stable cantilever electrode movable between an open position and a closed position. The shift register chain also includes a second non-volatile memory element coupled to the second NOR gate. The second non-volatile memory element includes a second pull-off electrode, a second contact electrode, a second pull-in electrode disposed adjacent the second contact electrode, and a second bi-stable cantilever electrode movable between an open position and a closed position. The shift register chain also includes a third non-volatile memory element coupled to the first NOR gate. The third non-volatile memory element includes a third pull-off electrode, a third contact electrode, a third pull-in electrode disposed adjacent the third contact electrode, and a third bi-stable cantilever electrode movable between an open position and a closed position. The shift chain register includes a fourth non-volatile memory element coupled to the second NOR gate. The fourth non-volatile memory element includes a fourth pull-off electrode, a fourth contact electrode, a fourth pull-in electrode disposed adjacent the fourth contact electrode, and a fourth bi-stable cantilever electrode movable between an open position and a closed position. The shift register chain may also include a first inverter coupled to both the first contact electrode and the second contact electrode and a second inverter coupled to both the third contact electrode and the fourth contact electrode. The shift register chain may be multipled such that an array of non-volatile memory pairs are used in an array.

In another embodiment, a shift register chain is disclosed. The shift register chain includes a first flip flop, a first AND gate coupled to the first flip flop and a first non-volatile memory element. The first non-volatile memory element may include a pull-off electrode, a pull-in electrode, a contact electrode adjacent the pull-in electrode and a bi-stable cantilever coupled to the first AND gate. Optionally, the first non-volatile memory element replaces a transistor within a circuit of two cross-coupled CMOS inverters.

In another embodiment, a latch is disclosed. The latch includes a first non-volatile memory element comprising a first pull-off electrode, a first contact electrode, a first pull-in electrode disposed adjacent the first contact electrode, and a first bi-stable cantilever electrode movable between an open position and a closed position. The latch also includes a second non-volatile memory element comprising a second pull-off electrode, a second contact electrode that is coupled to the first contact electrode, a second pull-in electrode disposed adjacent the second contact electrode, and a second bi-stable cantilever electrode movable between an open position and a closed position. The latch also includes a first program line coupled to the first non-volatile memory element, a first bitline coupled to the first cantilever, a second program line coupled to the second non-volatile memory element and a second bitline coupled to the second cantilever.

In another embodiment, a latch includes a first non-volatile memory element comprising a pull-off electrode, a pull-in electrode, a contact electrode adjacent the pull-in electrode and a bi-stable cantilever movable between a position in contact with the contact electrode and a position spaced therefrom. The latch also includes a first transistor having a first source electrode, a first drain electrode and a first gate electrode, a second transistor having a second source electrode, a second drain electrode and a second gate electrode and a third transistor having a third source electrode, a third drain electrode and a third gate electrode, wherein the second gate electrode and the third gate electrode are both coupled to the contact electrode and wherein the first source electrode is coupled to the contact electrode.

In another embodiment, a latch includes a first non-volatile memory element comprising a first pull-off electrode, a first contact electrode, a first pull-in electrode disposed adjacent the first contact electrode, and a first bi-stable cantilever electrode movable between an open position and a closed position. The latch may also include a second non-volatile memory element comprising a second pull-off electrode, a second contact electrode, a second pull-in electrode disposed adjacent the second contact electrode, and a second bi-stable cantilever electrode movable between an open position and a closed position. The latch may also include a first transistor having a first source electrode, a first drain electrode and a first gate electrode, wherein the first source electrode is coupled to the first contact electrode. The latch may additionally include a second transistor having a second source electrode, a second gate electrode and a second drain electrode coupled to the first drain electrode, wherein the second source electrode is coupled to the second contact electrode.

In another embodiment, a shift register chain is disclosed. The shift register chain includes one or more flip flops, each flip flop having a first NOR gate and a second NOR gate coupled thereto. The shift register chain may also include a first non-volatile memory element coupled to the first NOR gate and comprising a first pull-off electrode, a first contact electrode, a first pull-in electrode disposed adjacent the first contact electrode, and a first bi-stable cantilever electrode movable between an open position and a closed position. The shift register chain may also include a second non-volatile memory element coupled to the second NOR gate and comprising a second pull-off electrode, a second contact electrode, a second pull-in electrode disposed adjacent the second contact electrode, and a second bi-stable cantilever electrode movable between an open position and a closed position.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of a four-terminal, cantilever structure according to one embodiment.

FIG. 2 is an example of a possible architecture with two cantilever devices according to one embodiment.

FIG. 3 shows a two cantilever device structure with three active signals and a ground signal.

FIG. 4 shows the element of FIG. 3 with a CMOS inverter to provide a higher continuous drive capability.

FIG. 5 shows two combinations to create a crossbar switch from the memory element of FIGS. 3 and 4 CMOS transistors.

FIG. 6 shows a generic shift register chain.

FIG. 7 shows one embodiment of a shift register chain utilizing a cantilever structure.

FIG. 8 shows the programming sequence for the shift register chain of FIG. 7.

FIG. 9 shows a shift register chain similar to FIG. 6 utilizing cantilever structures as the latches.

FIG. 10 shows an array and programming logic according to one embodiment.

FIG. 11 shows the programming sequence for the shift register chain of FIG. 10.

FIG. 12 shows an array and programming logic according to another embodiment.

FIG. 13 shows the programming sequence for the shift register chain of FIG. 12.

FIG. 14 shows additional circuitry that may be used to avoid the ‘hot-switch’ current running through the cantilever in some embodiments.

FIGS. 15 and 16 show examples of latch implementations.

FIG. 17 shows a transistor level implementation of a non-volatile latch with a tri-state inverter feedback.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments discussed herein generally relate to utilizing non-volatile memory elements to continuously drive other circuitry. Examples of such non-volatile memory elements include micro-electromechanical systems (MEMS) based non-volatile memory elements. There are many advantages to utilizing non-volatile memory to continuously drive other circuitry. For example, back end of the line (BEOL) compatible process may be used to fabricate the non-volatile memory elements that does not affect any front end of the line (FEOL) devices. Other technologies are in the FEOL or use higher temperatures and non-standard materials, potentially causing issues with devices already created in the FEOL. This is of extra concern for the behavior of analog transistors in the FEOL and therefore this invention enables a much easier integration of this non-volatile process option in the existing semiconductor processes. This is specifically important for the analog and mixed-signal market, where the tolerances for the transistors are very tight and should not be altered by another process option. This also allows for an earlier integration of non-volatile technology into the latest state-of-the-art semiconductor process nodes. This is specifically important for FPGA and CPLDs, which make use of the latest process nodes.

The micro-electromechanical system (MEMS) based non-volatile technology can be used to create simple memory elements, which continuously drive another piece of circuitry. This can be used in tuning of analog circuits or programming elements of an FPGA. Other techniques usually read the information from an internal or external non-volatile memory, during a startup protocol, and store the information in latches, SRAM cells or flip flops at other parts of the chip, where the data is needed. Admittedly, within an FPGA, the information is stored in a distributed array of cells, which can be programmed as an SRAM memory, but the individual cells can continuously drive other elements of the FPGA.

As the data is already stored in a non-volatile manner at the point in the circuit where it is required, it does not require a startup protocol, where data from a non-volatile memory (internal or external) need to be sent over a bus towards the latches, flip flops or SRAM-cells inside the circuit. The thousands or millions of storage elements in an SRAM-based FPGA are built up with at least six transistors. All these storage elements can be replaced by pairs of MEMS-switches, which can be placed above the remaining transistors. This saves a lot of transistors and a lot of space on the chip.

Writing to these memory elements requires less power as it requires only capacitive power. As the leakage current of a MEMS-switch is less than the leakage current of a transistor, there are far less transistors required. Also, the power due to leakage is greatly reduced. The speed of writing data to these ‘continuously driving memory elements’ is much faster than with the existing flash and EEPROM non-volatile technologies. For analog and mixed signal devices, these memory elements need to be written during the functional production test on very expensive tester equipment. The faster writing speed will result in a reduced tester time and therefore less test costs.

Some applications require storing some settings during power-off or the detection of power-failure. These leave only limited time and limited power to execute such function. As this technology has a very low power write execution it allows for massive parallel writing of data as well as doing this at high speed. This makes this technology far superior over the existing flash and EEPROM technologies, which requires order of magnitude more power and time.

Some applications might also benefit from the faster write speed during its normal mode operation. FPGAs equipped with this technology do not require any external non-volatile memory. This saves board space, saves the cost of the external non-volatile memory, does not require a startup sequence at power-up and is more secure as the data can not be ‘tapped’ from the external memory. As the FPGAs can be made smaller (less transistors required, while the cantilever switches can be put on top of the remaining transistors), the extra costs of processing will be offset and the FPGAs will be cheaper, too.

The basic cantilever device has four electrical terminals as shown in FIG. 1. CANTI is the terminal connected to the mechanically movable cantilever. PO is the pull-off electrode, PI is the pull-in electrode and CO is the contact electrode. When there is a voltage difference between the cantilever and the pull-in electrode there will be an electrostatic force (PI_force) on both the pull_in electrode and the cantilever. As the pull_in electrode can not move, the bi-stable cantilever will move down and make electrical contact with the contact electrode (hence is in down position or closed). Table 1 is the truth table for the cantilever device of FIG. 1. The closed position refers to the cantilever in contact with the contact electrode, and the open position refers to the cantilever spaced form the contact electrode.

TABLE 1

| PI | PO | CANTI | OLD_POS | PI_force | PO_force | NEW_POS |
|---|---|---|---|---|---|---|
| 0 | 0 | 0 | CLOSED | 0 | 0 | CLOSED |
| 0 | 0 | 0 | OPEN | 0 | 0 | OPEN |
| 0 | 0 | 1 | CLOSED | ++ | + | CLOSED |
| 0 | 0 | 1 | OPEN | + | ++ | OPEN |
| 0 | 1 | 0 | CLOSED | 0 | + | OPEN |
| 0 | 1 | 0 | OPEN | 0 | ++ | OPEN |
| 0 | 1 | 1 | CLOSED | ++ | 0 | CLOSED |
| 0 | 1 | 1 | OPEN | + | 0 | CLOSED |
| 1 | 0 | 0 | CLOSED | ++ | 0 | CLOSED |
| 1 | 0 | 0 | OPEN | + | 0 | CLOSED |
| 1 | 0 | 1 | CLOSED | 0 | + | OPEN |
| 1 | 0 | 1 | OPEN | 0 | ++ | OPEN |
| 1 | 1 | 0 | CLOSED | ++ | + | CLOSED |
| 1 | 1 | 0 | OPEN | + | ++ | OPEN |
| 1 | 1 | 1 | CLOSED | 0 | 0 | CLOSED |
| 1 | 1 | 1 | OPEN | 0 | 0 | OPEN |

When the voltage difference between the cantilever and the pull-in electrode is removed, ‘stiction’ will keep the cantilever connected to the contact electrode. Stiction is a well-known phenomena in the MEMS world, which usually needs to be avoided, but in this case will make the device non-volatile. Obviously, we can also apply a voltage difference between the pull-off electrode and the cantilever, which will result in an electrostatic force (PO_force in) which will move the cantilever to make contact with the pull-off electrode. The pull-off electrode has an isolating layer, so there will not be conducting contact between the cantilever and the pull-off electrode. But the stiction will keep the cantilever in this position (hence in upper position or OPEN). The cantilevers can also be designed in such a way that they don't stick to the pull-off electrode. In such case, the cantilever dimensions should be designed such that when it is in its free position there is a stronger force towards the pull-off electrode than to the pull-in electrode in order to avoid a spurious pull-in, when the cantilever has a different voltage, while the both electrodes have an identical voltage. Table 1 shows all possible voltages on the 3 inputs and the current position of the device (OLD_POS) and the resulting new position (NEW_POS). The pull-in force (PI_force) and pull-off force (PO_force) are shown where ++ is a bigger force than +.

As shown in Table 1, when no voltage is applied to either the pull-in electrode, the pull-up electrode or the cantilever, the cantilever will not change its position. Similarly, when voltage is applied only to the cantilever, but not to the pull-off electrode or the pull-in electrode, the cantilever will not change its position. However, when the voltage is applied only to the cantilever, the force at the location where the cantilever is stationed will be greater. For example, if the cantilever is in the opened position and voltage is applied only to the cantilever, the cantilever will not change its position and the pull-in force will be less than the pull-off force. Similarly, if the cantilever is in the closed position and the voltage is applied only to the cantilever, the cantilever will not change position and the pull-in force will be greater than the pull-off force.

If voltage is applied to both the pull-off electrode and the pull-in electrode, but not to the cantilever, the cantilever will not change its position. Similarly, if voltage is applied to the pull-in electrode, the pull-off electrode and the cantilever, the cantilever will not change its position.

When there is a voltage difference between the cantilever and with the pull-off electrode or the pull-in electrode, the cantilever may move. For example, if voltage is applied only to the pull-off electrode and not the cantilever or the pull-in electrode, the cantilever will move to the open position (if not already in the open position). Similarly, if voltage is applied only to the pull-in electrode and not the cantilever or the pull-off electrode, the cantilever will move to the closed position (if not already in the closed position).

When there is a voltage applied to the cantilever and either the pull-in electrode or the pull-off electrode, the cantilever will move to the non-powered electrode. For example, if voltage is applied to the pull-in electrode and the cantilever, the cantilever will move to the open position (if not already in the open position). Similarly, if voltage is applied to the pull-off electrode and the cantilever, the cantilever will move to the closed position (if not already in the closed position).

For some applications it is required that a memory element is capable of continuously driving either a value of ‘1’ or ‘0’. These memory elements will continuously drive other circuitry to put it into a certain programmable state. This is different with respect to a memory, where the memory element only needs to drive the bitline when it is selected.

When the cantilever is not connected to the contact electrode (hence: ‘open’), it can not drive a signal. It can only drive when it is connected to the contact electrode and also only with a limitation with respect to the amount of current through the cantilever. Therefore, it is required to use two cantilever devices in order to define a signal, which can either drive a ‘1’ or drive a ‘0’.

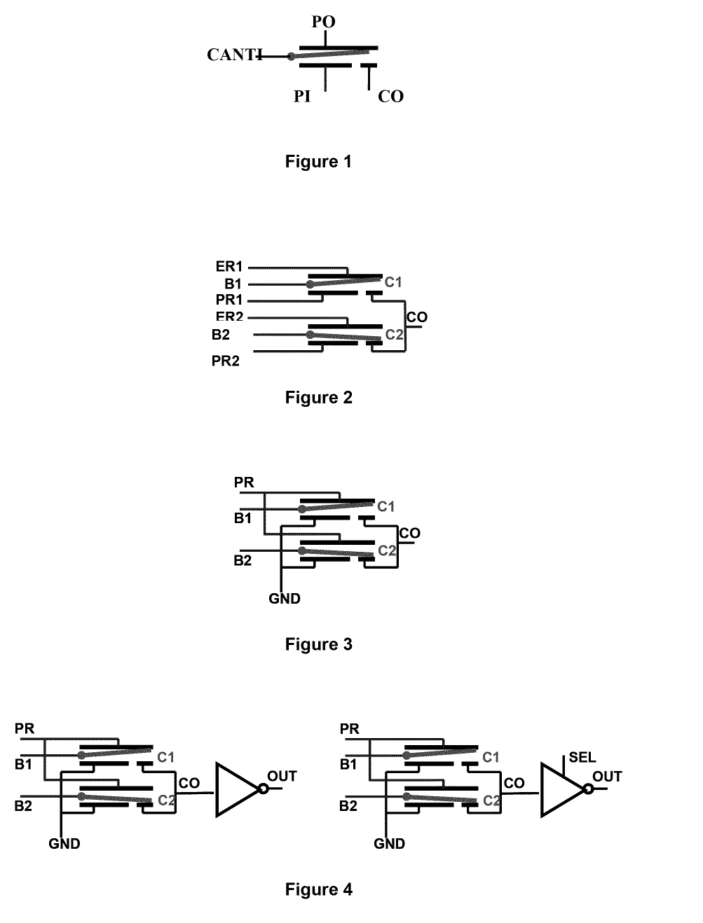

FIG. 2 is an example of a possible architecture with two cantilever devices. The essential part of the combination is the fact that both contact electrodes are connected together. The load of the signal CO needs to be limited to avoid high currents through the cantilever contacts. No resistive load should be connected as this might also cause a DC current through a cantilever.

The six input signals (ER2, B2, PR2, ER1, B1, ER1) can be used in any combination. ER1 and ER2 are the erase lines, B1 and B2 are the bitlines and PR1 and PR2 are the program lines. Having both cantilevers in a programmed state should be avoided while both B2 and B1 are at opposite voltages. In such case, a short occurs, which will damage the cantilever devices.

Many derivative wiring schemes can be applied to the basic cell to reduce the amount of signals and some will have different advantages and disadvantages than others. FIG. 3 shows an example with three active signals and a ground signal. It is also possible to replace the ground signal in FIG. 3 by Vdd and the other signals will be using inverted logic. The following truth diagram applies to this single memory element. The state of a cantilever (C1 or C2) is either CLOSED (‘C’) or OPEN (‘O’) and can change from position during a write or erase state, where C1 and C2 are the contact electrodes. Table 2 is the truth table of the FPGA element of FIG. 3.

TABLE 2

| PR | B1 | B2 | C1 | C2 | CO | NOTE |
|---|---|---|---|---|---|---|
| 0 | 0 | 0 | C→C | O→O | B1 = 0 | During Erase state of |
| | | | | | | other device |
| 0 | 0 | 0 | O→O | C→C | B2 = 0 | During Erase state of |
| | | | | | | other device |
| 0 | 0 | 1 | C→C | O→O | B1 = 0 | Normal ‘0’-state or |
| | | | | | | Write ‘1’ of other device |
| 0 | 0 | 1 | O→O | C→C | B2 = 1 | Normal ‘1’-state or |
| | | | | | | Write ‘1’ of other device |
| 0 | 1 | 0 | C→C | O→O | B1 = 1 | During Write ‘0’ of |
| | | | | | | other device |
| 0 | 1 | 0 | O→O | C→C | B2 = 0 | During Write ‘0’ of |
| | | | | | | other device |
| 0 | 1 | 1 | C→C | O→O | B1 = 1 | Invalid mode |
| 0 | 1 | 1 | O→O | C→C | B2 = 1 | Invalid mode |
| 1 | 0 | 0 | C→O | O→O | Float | Erase state |
| 1 | 0 | 0 | O→O | C→O | Float | Erase state |
| 1 | 1 | 0 | O→C | O→O | B1 = 1 | Write ‘0’ |
| 1 | 0 | 1 | O→O | O→C | B2 = 1 | Write ‘1’ |
| 1 | 1 | 1 | x→C | x→C | B1 = B2 = 1 | Invalid mode |

In normal operation PR=‘0’, B1=‘0’ and B2=‘1’. The state of the two complementary cantilevers (C1 and C2) defines the value of the memory element, as either B1 or B2 is connected to the output node CO, through one of the two cantilevers. During programming, the value of B1 and B2 will be changed in order to allow the cantilevers to move. As the signals can be connected to more memory elements, this also means that during programming of these other memory elements B1 and B2 will get another value. Hence, the output value CO has temporarily an invalid value, but it will not change the position of the cantilevers and therefore it keeps its ‘state’ and the memory element will return to its normal value, once B1=‘0’ and B2=‘1’ again. There are three invalid modes in the arrangement of FIG. 3. The invalid modes occur when a voltage is applied using both bitlines (B1 and B2).

Potentially, both cantilevers can be touching the contact electrode simultaneously during programming, when the unprogrammed cantilever switches faster and touches the contact electrode, while the programmed cantilever has not started to switch its position yet. For this reason, an erase of both cantilevers is recommended directly prior to a writing event. This will leave both contact electrodes and, therefore, the input of the inverter floating for a short period of time. The input capacitance of the inverter will keep the voltage on this node at a ‘0’ or ‘1’ level for sufficient time to guarantee an erase and write event. In the case it can be guaranteed that during programming, the programmed cantilever will always release from the contact electrode before the unprogrammed cantilever will make contact with the contact electrode, the erase mode can be skipped.

FIG. 4 shows the element of FIG. 3 with a CMOS inverter to provide a higher continuous drive capability. Signal CO is only connected to both the gate of a NMOS transistor and the gate of a PMOS transistor, which is a very small capacitive load.

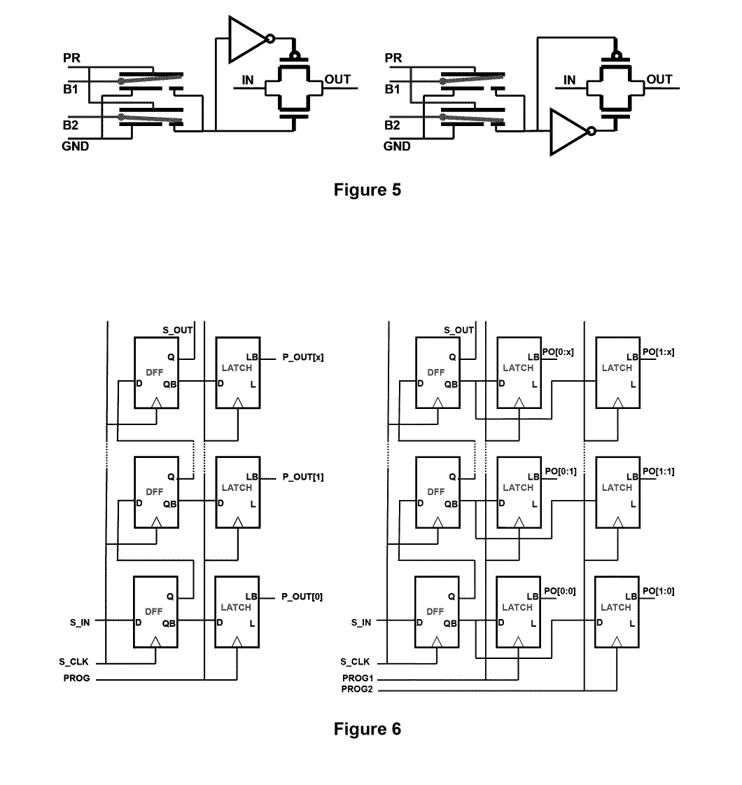

FIG. 5 shows two combinations to create a crossbar switch from the memory element of FIGS. 3 and 4 CMOS transistors. The load of signal CO is still only the gate capacitance of 3 CMOS transistors, which is also still a very small capacitive load. Such device can typically be used to create a programmable routing element in an FPGA or switch on or off a passive element in an analog calibration circuit.

Here are further examples for controlling the signals PR, B1 and B2 when there are more memory elements in a chip. No described is an example where only a few bits will be driven by a chain of shift registers. When (near) unlimited of program and erase actions can be executed on cantilever switches, the latch can also be integrated into the shift register. In this case, we assume a limited amount of program and erase actions for a cantilever device. Therefore, it is not recommended to include a non-volatile latch inside the shift register chain, but add it as an extra parallel latch to a shift register chain. This also provides the ability that the non-volatile latches keep their function, while data gets shifted into the shift register chain. Once all the data has been serially shifted into the shift register chain, a parallel program action can be executed to provide the non-volatile latches with new data. Such a generic shift register chain is described at the left hand side of FIG. 6. Signal S_CLK controls the shift register chain and S_IN provides the data-stream to the chain. The signal PROG is used to copy the data from the shift register chain into the parallel latches and store the data for its functional use. When there is a lot of data to store, it is possible to re-use the same shift register chain to store data in different latches. It requires just another programming signal which copies data into the other latches as is shown in the right hand side of FIG. 6.

Now the latches of FIG. 6 need to be created with the latch of FIG. 4. This will require some additional logic as there are two phases (erase and program) to copy data into the latch and it also requires two input signals which are manipulated during these phases.

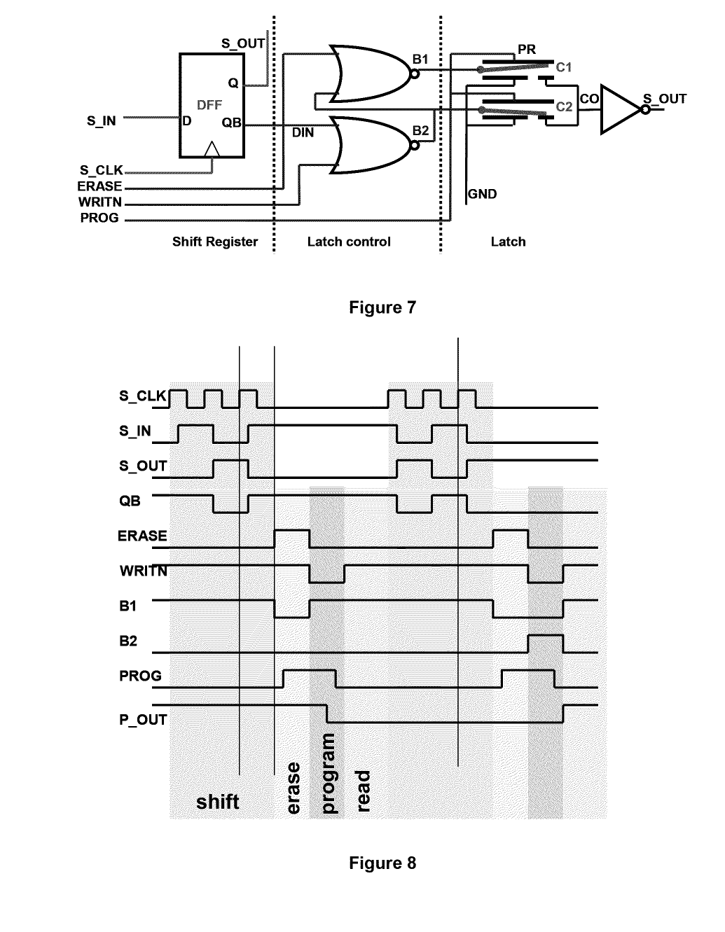

FIG. 7 shows one example of such replacement. The flip flop for the shift register remains the same, but there are two NOR-gates connected to the output of this flip flop to create the two signals B1 and B2 as described in FIGS. 1, 3 and 4. These NOR-gates are also fed with an ERASE and WRITN signal, which determine the two phases of a programming event. Signal PROG will be high during the two consecutive active state of ERASE (active high) and WRITN (active low). The simple logic to determine the ERASE and WRITN signals from the PROG signal needs only to be created once. As the two NOR-gates are only required once per flip flop and can drive multiple latches, it can be seen as extra logic belonging to the flip flop. A programming sequence will first require shifting in the data, followed by an erase mode (if required as described at Table 2) prior to the write mode and is described in FIG. 8.

Shifting in data will be done by providing the right data on signal S_IN and toggling the clock signal S_CLK. For the ERASE mode, the ERASE signal needs to go high closely followed by the PROG signal. When the erase is finished, the ERASE signal is removed and the WRITN signal becomes low to move to the write mode. The write mode is finished by making the PROG signal low and the WRITN signal high again. Note that the programming of a zero (i.e., low on P_OUT) will be effective immediately, and programming of a one will become effective after the write mode has closed.

As explained below Table 2 it might be possible to skip the erase mode, hence the erase signal in FIG. 7. FIG. 7 is not required and the NOR-gate, which has the erase signal as input can be reduced to an inverter with only the output of the other NOR-gate as input. In such case, the WRITN signal can also become just an inversion of the PROG signal.

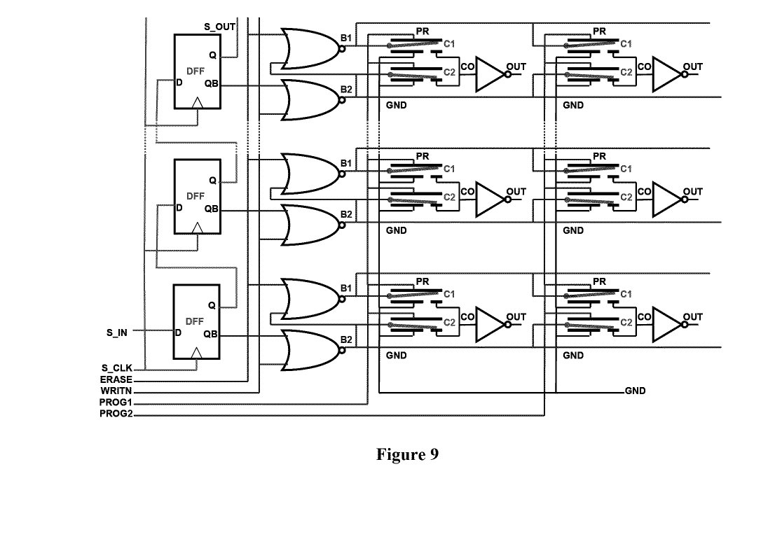

FIG. 9 shows how the circuit of FIG. 7 can be duplicated to make the exact same circuit as is shown on the right hand side of FIG. 6, with the exception of the logic to create the ERASE and WRITN signal. It shows only a combination of two latches per shift register, but this can be any amount of non-volatile latches per shift-register.

Within a FPGA architecture it is required to program millions of individual elements with either a value of ‘1’ or ‘0’. Therefore these elements will be placed in an array along with the logic which will be driven by these elements. Some additional logic is required around the array to program the array. In fact, FIG. 9 is the basis to form such an array.

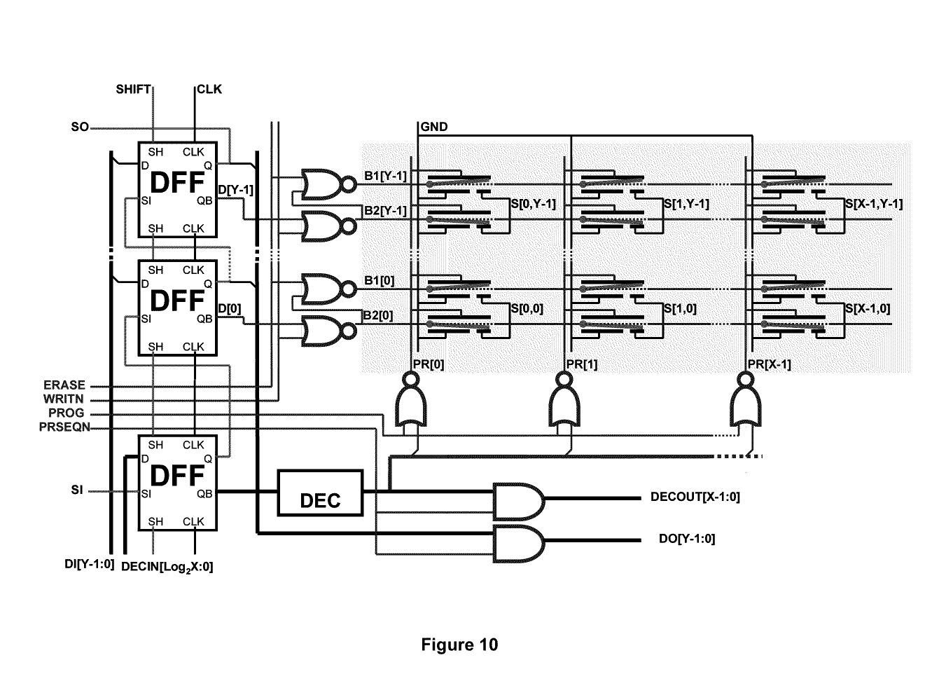

FIG. 10 is used as an example for such an array and programming logic. The logic inside the array (crossbar switches, LUTs, etc. are not drawn). The circuitry, which is only used during the programming sequence, comprise NOR and AND gates. The register chain is designed as such that the flip flops can be reused in the functional mode. The logic outside the array may be powered by signal VDD_P, while all logic (i.e., all transistors) inside the array may be powered by signal VDD_A. The array may be powered off during the full programming sequence (PRSEQN=0) to avoid any conflicts (like shorts) during programming, but it can also be managed by programming in a certain sequence or using the right crossbar switches. The NOR-gates are used to program the array and the AND-gates can be used to disable the re-used signals, before they go into the programmable array. Also these AND-gates may not be required and can be optimized away.

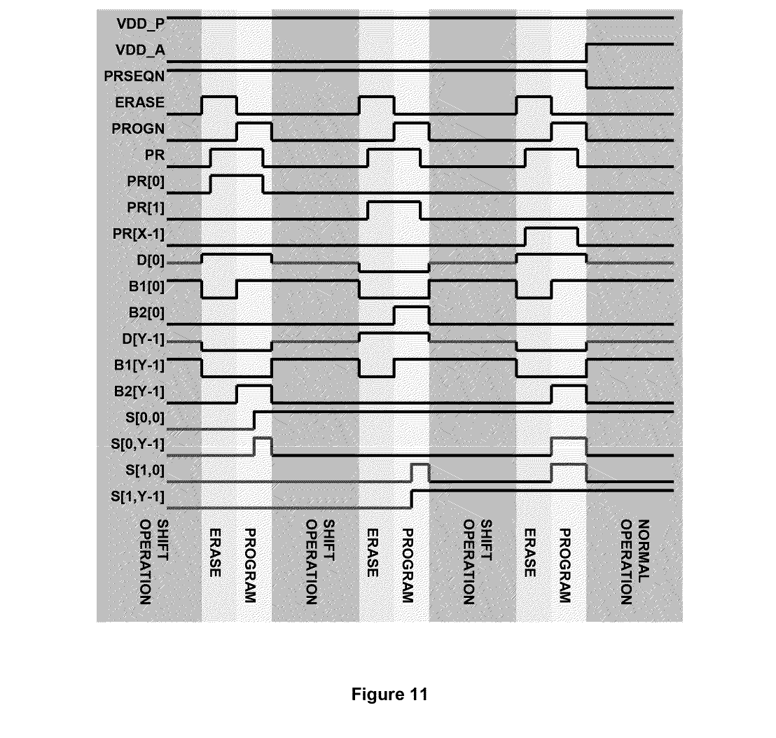

The timing of such array is described in FIG. 11. During the erase and program cycles, the memory elements do not provide the appropriate value and these signals have been given the color blue during these cycles. So, during the programming sequence of such an array, the values of the programmed bits are temporarily invalid during the erase and programming cycle of another bit. Therefore the ‘array’ can only be ‘validated’, once the whole array has been filled with the right content. This is the reason why the power supply (VDD_A) of all circuitry inside the array should be powered off, during the full programming sequence of many shift, erase and program cycles. This will avoid potential temporary shorts in the routing network of the FPGA device, during the programming sequence.

As one can see, only for nodes programmed to ‘0’, there can be a disturbance to ‘1’ during program cycles of subsequent write events. When the realized crossbar-switches are designed to be only active when programmed to ‘0’ (see right side of FIG. 5), these disturbances can not lead to short circuits as these disturbances can only switch off a crossbar-switch. Therefore the power supply of the array circuitry (VDD_A) and the power supply of the programming logic (VDD_P) may be connected, when the order of programming is guaranteed and an initial reset of the combined cantilevers is guaranteed.

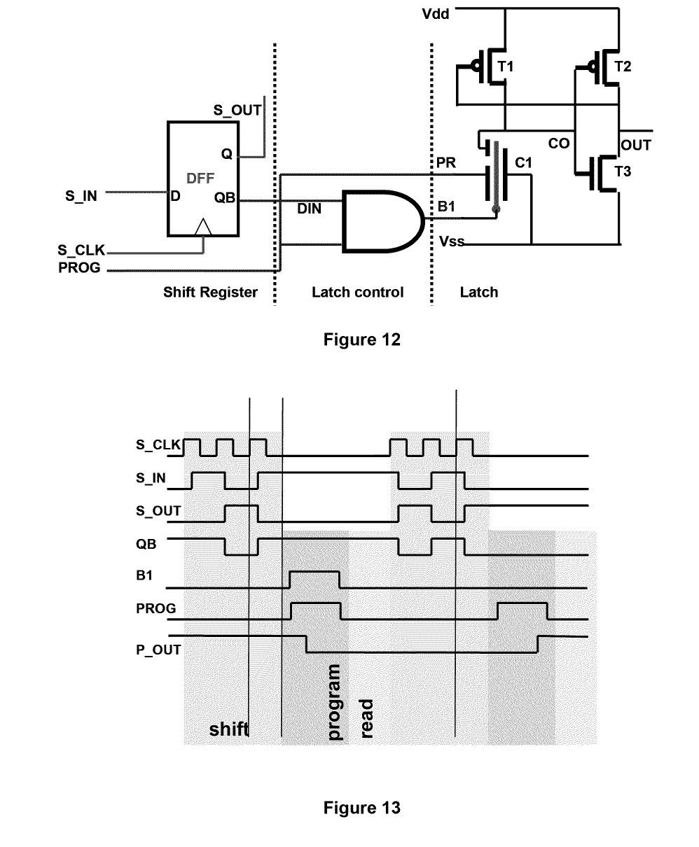

There are other possibilities to create latches based on cantilever devices. FIG. 12 shows an alternative example with the exact same functionality as FIG. 7. The latch in FIG. 12 contains only one cantilever switch, while the other cantilever is replaced by a PMOS transistor T1 with an active feedback from the inverter formed by transistors T2 and T3. The program mode is not separated in an erase and program part anymore. Table 3 shows the truth table for the latch of FIG. 12.

TABLE 3

| PR | B1 | C1 | CO | OUT | NOTE |
|---|---|---|---|---|---|
| 0 | 0 | C→C | 0 | 1 | Normal ‘1’-state |
| 0 | 0 | O→O | 1 | 0 | Normal ‘0’-state |
| 0 | 1 | C→C | 1 | 0 | Invalid mode, will be prohibited by |
| | | | | | latch control May occur as a ‘glitch’ |
| | | | | | in an array mode |
| 0 | 1 | O→O | 1 | 0 | Invalid mode, will be prohibited |
| | | | | | by latch control |
| 1 | 0 | C→C | 0 | 1 | Write ‘1’ (overwrite ‘1’) |
| 1 | 0 | O→C | 0 | 1 | Write ‘1’ (overwrite ‘0’) |
| 1 | 1 | C→O | 1 | 0 | Write ‘0’ (overwrite ‘1’) |
| 1 | 1 | O→O | 1 | 0 | Write ‘0’ (overwrite ‘0’) |

When the latch is in the normal 1′-state, the cantilever is closed and B1 is ‘0’. Therefore, the intermediate signal CO is ‘0’ and the inverter provides a ‘1’, which is fed back to the gate of PMOS transistor T1. Therefore, this transistor will be switched-off and no current will run through this transistor or the cantilever. When the latch needs to be switched to a normal ‘0’-state, both PR and B1 need to be made ‘1’. As the cantilever will not switch instantaneous, the ‘1’ from B1 will be propagated to CO, the inverter will provide a ‘0’ to the gate of PMOS transistor T1 and will switch on this transistor keeping the signal CO at ‘1’. When the cantilever will open, the signal CO will remain ‘1’ as the feedback transistor will keep it in place.

When the latch needs to be switched back from ‘0’-state to ‘1’-state, PR is ‘1’ and B1 is ‘0’, while CO still is ‘1’. When the cantilever touches the contact (hot switch), current will flow through transistor T1 and the cantilever. Therefore T1 needs to be a weak transistor, so that CO will still go to a low-voltage value and the inverter will swap and switch off transistor T1 and stabilize the latch. Although, the cantilever should be able to survive such current for a small amount of time, it might be recommended to avoid such current. The latch of FIG. 12 may be used in either a 1-dimensional or a multi-dimensional array such as shown in FIGS. 9 and 10. When the latch of FIG. 12 is placed into the array of FIG. 9 or 10, the NOR gates may be replaced by one or two AND gates.

FIG. 13 is the timing diagram for this ‘one cantilever latch’. There is only one programming mode, which will either write a ‘1’ or a ‘0’. There is no erase mode required anymore prior to the programming mode. The latch from FIG. 12 can also replace the ‘2-cantilever latches’ in FIGS. 9 and 10, while the control logic needs to get adapted accordingly.

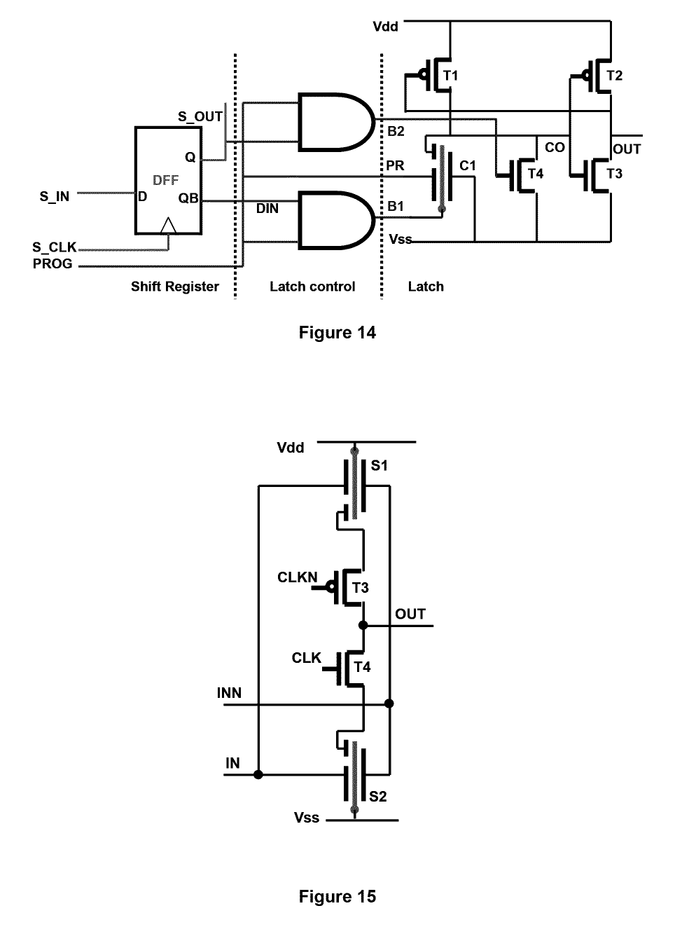

FIG. 14 includes additional circuitry to avoid the ‘hot-switch’ current running through the cantilever. When the cantilever needs to be closed, signal B2 gets activated (‘1’) and will switch on transistor T4, which will have a stronger drive than T1 making sure CO will go to a low voltage and OUT will become ‘1’ and therefore T1 will be switched off and CO will become ‘0’, before the cantilever will close. Now the ‘hot-switch’ current runs through the added transistor T4, while also the output signal will switch to ‘1’ faster. This latch can not be used to replace the latches in FIGS. 9 and 10 as signal B2 will overwrite all latches in the same row.

During power-down and power-up of the circuitry, no programming activities are allowed. During power-down the switch C1 will stay in its position. During power-up, while the switch is closed, the internal signal CO is grounded and therefore the output signal will become high, switching off transistor T1. During power-up, while the switch is open, CO is floating and it will require some noise to have the output to switch to its proper position. Therefore the timing for power-up is a little hard to predict. The latch of FIG. 14 may be used in either a 1-dimensional or a multi-dimensional array such as shown in FIGS. 9 and 10. When the latch of FIG. 14 is placed into the array of FIG. 9 or 10, the NOR gates may be replaced by one or two AND gates.

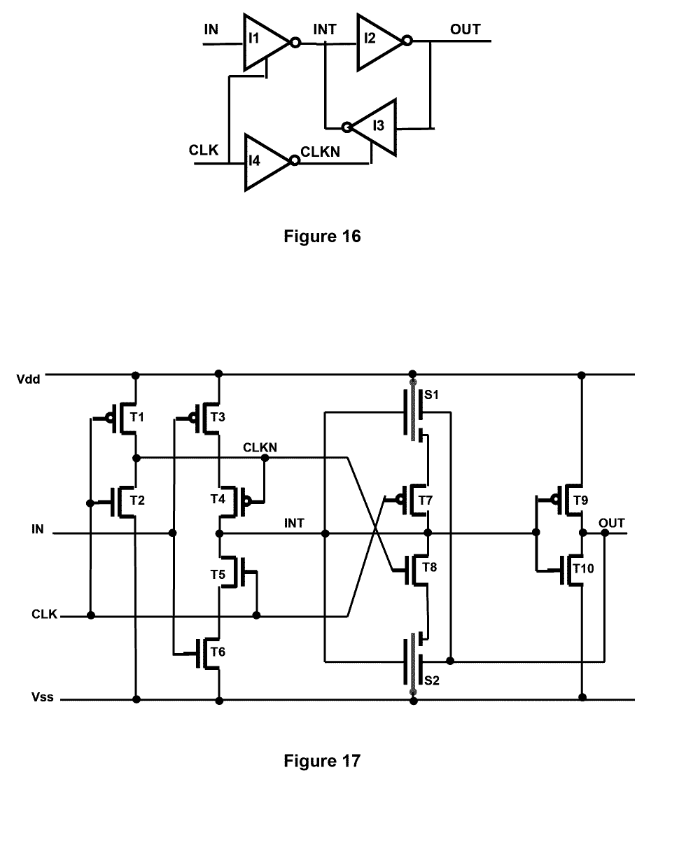

FIGS. 15 and 16 show examples of a standard latch implementation. When the CLK is high, the tri-state inverter I1 propagates the input signal IN propagates to the inverted internal signal INT and the output inverter (12) inverts it again to make it the output signal OUT. When the CLK is low, the tri-state inverter I3 takes over from I1 and feeds back the output signal to INT, making sure the output signal is kept stable. Inverter I4 provides the inverted clock signal. There is a lot of prior art know-how available with respect to issues and solution with respect to such latches. In this document we only concentrate on altering such circuit to make it non-volatile by using MEMS switches. When the latch of FIG. 15 is used in either a 1-dimensional array or a multi-dimensional array, no NOR or AND gates are necessary as the latch may be coupled directly to the complement input signal and the complement clock or program signal.

Only the tri-state inverter I3 gets changed and the rest of the circuitry remains the same. A tri-state inverter usually consists of two PMOS and two NMOS transistors. The PMOS and NMOS transistor which have their gates connected to the input signal get swapped by two cantilever devices, while the devices which are connected to the clock signals remain. In order to keep a known voltage on the cantilever it is recommend to place these devices at the power-rail. As the cantilever switches are non-volatile, they also require an inverting input signal at the opposite pull-electrode to mimic a volatile behavior. CLKN is the inverted signal of CLK, while the circuitry to provide this is not included.

FIG. 17 is a transistor level implementation of the non-volatile latch with a tri-state inverter feedback. The input signal propagates to the internal signal when CLK is high and this is the moment a potential switching of the two cantilevers can occur. During the switching of the cantilevers the transistors T7 and T8 are off, making sure no shorting of the cantilevers will occur. A “DC path” can only occur when either T3, T4 and T8 are on, while S2 is closed or when T5, T6 and T7 are on, while S1 is closed. With proper design of T4-T8 and T5-T7 combinations and fast switching clocks this can be prohibited.

Assuming a stable input signal during the time CLK is high, guarantees that the signal INT has a clear defined value, which will be identical to the value which the tri-state feedback inverter will provide when it is switched on (hence CLK goes low). Therefore there will be (hardly) any current running through the cantilevers at any time. At the time of switching a cantilever it will only charge or discharge the source/drain capacitance of either transistor T7 or T8.

During power off and power down, CLK should be low, so that cantilevers will not switch during these modes. During power-up, either S1 or S2 is closed and therefore the internal signal INT will be connected to either Vdd or Vss. This guarantees a good power-up behavior and is therefore the recommended architecture.

While the foregoing is directed to embodiments of the present invention, other and further embodiments of the invention may be devised without departing from the basic scope thereof, and the scope thereof is determined by the claims that follow.

1. A latch, comprising:
a first non-volatile memory element comprising a first pull-off electrode, a first contact electrode, a first pull-in electrode disposed adjacent the first contact electrode, and a first bi-stable cantilever electrode movable between an open position and a closed position;
a second non-volatile memory element comprising a second pull-off electrode, a second contact electrode that is coupled to the first contact electrode, a second pull-in electrode disposed adjacent the second contact electrode, and a second bi-stable cantilever electrode movable between an open position and a closed position;
a first program line coupled to the first non-volatile memory element;
a first bitline coupled to the first cantilever;
a second program line coupled to the second non-volatile memory element; and
a second bitline coupled to the second cantilever.

2. The latch of claim 1, further comprising:
a first erase line coupled to the first pull-off electrode; and
a second erase line coupled to the second pull-off electrode, wherein the first program line is coupled to the first pull-in electrode and the second program line is coupled to the second pull-in electrode.

3. The latch of claim 1, wherein the first program line is coupled to the first pull-off electrode, the second program line is coupled to the second pull-off electrode, the first program line and the second program line are coupled together, the first pull-in electrode is coupled to ground and the second pull-in electrode is coupled to ground.

4. A latch, comprising:
a first non-volatile memory element comprising a pull-off electrode, a pull-in electrode, a contact electrode adjacent the pull-in electrode and a bi-stable cantilever movable between a position in contact with the contact electrode and a position spaced therefrom;
a first transistor having a first source electrode, a first drain electrode and a first gate electrode;
a second transistor having a second source electrode, a second drain electrode and a second gate electrode; and
a third transistor having a third source electrode, a third drain electrode and a third gate electrode, wherein the second gate electrode and the third gate electrode are both coupled to the contact electrode and wherein the first source electrode is coupled to the contact electrode.

5. The latch of claim 4, further comprising:
a fourth transistor having a fourth source electrode, a fourth drain electrode and a fourth gate electrode, wherein the fourth source electrode is coupled to the contact electrode.

6. The latch of claim 5, further comprising:
a first bitline coupled to the cantilever; and
a second bitline coupled to the fourth gate electrode.

7. A latch, comprising:
a first non-volatile memory element comprising a first pull-off electrode, a first contact electrode, a first pull-in electrode disposed adjacent the first contact electrode, and a first bi-stable cantilever electrode movable between an open position and a closed position;
a second non-volatile memory element comprising a second pull-off electrode, a second contact electrode, a second pull-in electrode disposed adjacent the second contact electrode, and a second bi-stable cantilever electrode movable between an open position and a closed position;
a first transistor having a first source electrode, a first drain electrode and a first gate electrode, wherein the first source electrode is coupled to the first contact electrode; and
a second transistor having a second source electrode, a second gate electrode and a second drain electrode coupled to the first drain electrode, wherein the second source electrode is coupled to the second contact electrode.

8. A shift register chain, comprising:
one or more flip flops, each flip flop having a first NOR gate and a second NOR gate coupled thereto;
a first non-volatile memory element coupled to the first NOR gate and comprising a first pull-off electrode, a first contact electrode, a first pull-in electrode disposed adjacent the first contact electrode, and a first bi-stable cantilever electrode movable between an open position and a closed position; and
a second non-volatile memory element coupled to the second NOR gate and comprising a second pull-off electrode, a second contact electrode, a second pull-in electrode disposed adjacent the second contact electrode, and a second bi-stable cantilever electrode movable between an open position and a closed position.

9. The shift register chain of claim 8, further comprising:
a first bitline coupled between the first NOR gate and the first cantilever; and
a second bitline coupled between the second NOR gate and the second cantilever.

10. The shift register chain of claim 9, wherein the first NOR gate is coupled to the shift register and a written signal source and the second NOR gate is coupled to the first bitline and an erase signal source.

11. The shift register chain of claim 10, wherein the first pull-off electrode and the second pull-off electrode are both coupled to the same program signal source.

12. The shift register chain of claim 11, wherein the first pull-in electrode and the second pull-in electrode are both coupled to ground and the shift register chain further comprises an inverter coupled to both the first contact electrode and the second contact electrode.

13. The shift register chain of claim 8, further comprising:
a third non-volatile memory element coupled to the first NOR gate and comprising a third pull-off electrode, a third contact electrode, a third pull-in electrode disposed adjacent the third contact electrode, and a third bi-stable cantilever electrode movable between an open position and a closed position; and
a fourth non-volatile memory element coupled to the second NOR gate and comprising a fourth pull-off electrode, a fourth contact electrode, a fourth pull-in electrode disposed adjacent the fourth contact electrode, and a fourth bi-stable cantilever electrode movable between an open position and a closed position.

14. The shift register chain of claim 13, further comprising:
a first bitline coupled to the first NOR gate, the first cantilever and the third cantilever; and
a second bitline coupled to the second NOR gate, the second cantilever and the fourth cantilever.

15. The shift register chain of claim 14, wherein the first NOR gate is coupled to the shift register and a written signal source and the second NOR gate is coupled to the first bitline and an erase signal source.

16. The shift register chain of claim 15 wherein the first pull-off electrode and the second pull-off electrode are both coupled to a first program signal source.

17. The shift register chain of claim 16, wherein the third pull-off electrode and the fourth pull-off electrode are both coupled to a second program signal source.

18. The shift register chain of claim 17, wherein the first pull-in electrode, the second pull-in electrode, the third pull-in electrode and the four pull-in electrode are each coupled to ground.

19. The shift register chain of claim 18, wherein the plurality of flip flops comprises a first flip flop and a second flip flop and wherein the first program signal source is coupled to the first pull-off electrode of the first flip flop, the second pull-off electrode of the first flip flop, the first pull-off electrode of the second flip flop and the second pull-off electrode of the second flip flop.

20. The shift register chain of claim 19, wherein the written signal source is coupled to the first NOR gate of the first flip flop and the first NOR gate of the second flip flop and the shift register chain further comprises a first inverter coupled to both the first contact electrode and the second contact electrode and a second inverter coupled to both the third contact electrode and the fourth contact electrode.
